(19) United States
(12) Patent Application Publication
(10) Pub. No.: US 2025/0323620 A1
(43) Pub. Date: Oct. 16, 2025

(54) SURFACE ACOUSTIC WAVE (SAW) DEVICE WITH HIGH-DIELECTRIC-CONSTANT MATERIAL

(71) Applicant: RF360 Singapore Pte. Ltd., Singapore (SG)

(72) Inventors: Tomasz JEWULA, Markt Schwaben (DE); Nicolas RAAB, München (DE)

(21) Appl. No.: 18/631,850

(22) Filed: Apr. 10, 2024

(51) Int. Cl. H03H 9/145; H03H 3/08; H03H 9/02; H03H 9/64

(52) U.S. Cl. CPC H03H 9/14538; H03H 3/08; H03H 9/02834; H03H 9/14502; H03H 9/6489; H03H 9/02992

(57) ABSTRACT

Certain aspects of the present disclosure are directed towards a SAW device. The SAW device may include a piezoelectric layer; an interdigital transducer (IDT) disposed above the piezoelectric layer and comprising a first electrode finger and a second electrode finger; and a first high-dielectric-constant (high-κ) material disposed between the first electrode finger and the second electrode finger, wherein a height of the first high-κ material above the piezoelectric layer is more than 60% of a height of the first electrode finger or the second electrode finger above the piezoelectric layer.

### TECHNICAL FIELD

Certain aspects of the present disclosure relate generally to electronic components and, more particularly, to surface acoustic wave (SAW) devices.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high frequency (e.g., generally greater than 100 MHZ) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices such as cellular phones).

Today, surface acoustic wave (SAW) or bulk acoustic wave (BAW) components may be used in wireless communication devices, such as for implementing RF filters. In SAW technology, the acoustic wave propagates laterally on a surface of a piezoelectric substrate (or a piezoelectric layer in examples where there are additional layers below the piezoelectric layer), with the movement of the piezoelectric generated by metal interdigitated transducers (IDTs) on the surface. The wavelength of the acoustic wave may be defined by the pitch (e.g., the spacing between fingers, which may be defined as the width of the metal finger and gap from one edge of a finger to a corresponding edge on an adjacent finger) of the IDT. In BAW technology, the acoustic wave propagates vertically through a three-dimensional structure, with an electric field applied through electrodes above and below a piezoelectric material. The wavelength, in this case, is defined by the thickness of the piezoelectric material.

In some types of SAW devices, a surface acoustic wave is generated by an input IDT and detected by an output IDT. In other types of SAW devices, the acoustic energy may be confined using reflectors on either side of the IDT. A planar resonant cavity created between two mirrors consisting of reflecting metal strips can also be used to trap the acoustic energy.

As the number of frequency bands used in wireless communications increases and as the desired frequency band of filters widen, the performance of acoustic filters increases in importance to reduce losses and increase overall performance of electronic devices. Acoustic filters with improved performance, particularly filters with reduced mechanical losses and self-heating, are therefore sought after.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include a reduction in a size of a surface acoustic wave (SAW) device.

Certain aspects of the present disclosure are directed towards a SAW device. The SAW device may include a piezoelectric layer; an interdigital transducer (IDT) disposed above the piezoelectric layer and comprising a first electrode and a second electrode; and a first high-dielectric-constant (high-κ) material disposed between the first electrode and the second electrode, wherein a height of the first high-κ material above the piezoelectric layer is more than 60% of a height of the first electrode or the second electrode above the piezoelectric layer.

Certain aspects of the present disclosure are directed towards a method of fabricating a SAW device. The method generally includes: forming an IDT disposed above a piezoelectric layer, wherein forming the IDT comprises forming a first electrode and a second electrode; and forming a first high-κ material such that the first high-κ material is between the first electrode and the second electrode, wherein a height of the first high-κ material above the piezoelectric layer is more than 60% of a height of the first electrode or the second electrode above the piezoelectric layer.

Certain aspects of the present disclosure are directed towards a wireless device. The wireless device generally include a radio frequency (RF) circuit and a SAW filter coupled to the RF circuit, the SAW filter comprising: a piezoelectric layer; an IDT disposed above the piezoelectric layer and comprising a first electrode and a second electrode; and a high-κ material disposed between the first electrode and the second electrode, wherein a height of the high-κ material above the piezoelectric layer is more than 60% of a height of the first electrode or the second electrode above the piezoelectric layer.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1A is a perspective view of an example electroacoustic device, in which certain aspects of the present disclosure may be practiced.

FIG. 1B is a cross-sectional view of the example electroacoustic device of FIG. 1A.

FIG. 2A is a top view of an example electrode structure of an electroacoustic device, in which certain aspects of the present disclosure may be practiced.

FIG. 2B is a top view of another example electrode structure of an electroacoustic device, in which certain aspects of the present disclosure may be practiced.

FIG. 3 is a cross-sectional view of an example electroacoustic device with a continuous thin layer of a dielectric material deposited on a piezoelectric layer prior to electrode deposition.

FIG. 4 illustrates a cross-section of a surface acoustic wave (SAW) device with an interdigital transducer (IDT) and with high-κ material disposed between electrodes of the IDT, in accordance with certain aspects of the present disclosure.

FIG. 5 illustrates a cross-section of a SAW device with high-κ material manufactured with a sacrificial layer, in accordance with certain aspects of the present disclosure.

FIG. 6 is a block diagram of example operations for fabricating a SAW device, in accordance with certain aspects of the present disclosure.

FIG. 7 is a schematic diagram of an electroacoustic filter circuit.

FIG. 8 is a functional block diagram of at least a portion of an example simplified wireless transceiver circuit in which the filter circuit of FIG. 7 may be employed.

FIG. 9 is a diagram of an environment that includes an electronic device that includes a wireless transceiver such as the transceiver circuit of FIG. 8.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to a surface acoustic wave (SAW) device with an interdigitated transducer (IDT) implemented with high-dielectric-constant (high-κ) material (e.g., also referred to as high-permittivity material) between electrodes to increase the static capacitance of the IDT. For example, the static capacitance of the IDT for the SAW filter may be increased by filling the entire space (or at least a majority of the space) between the electrodes of the IDT with high-κ material. The height of the high-material may be at least 60% of the height of the electrode. Increasing the static capacitance of the IDT increases the static capacitance of the SAW device, allowing for the size of the SAW device to be reduced by reducing the number of fingers of the IDT.

The detailed description set forth below in connection with the appended drawings is intended as a description of exemplary implementations and is not intended to represent the only implementations in which the invention may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

### Example Electroacoustic Devices

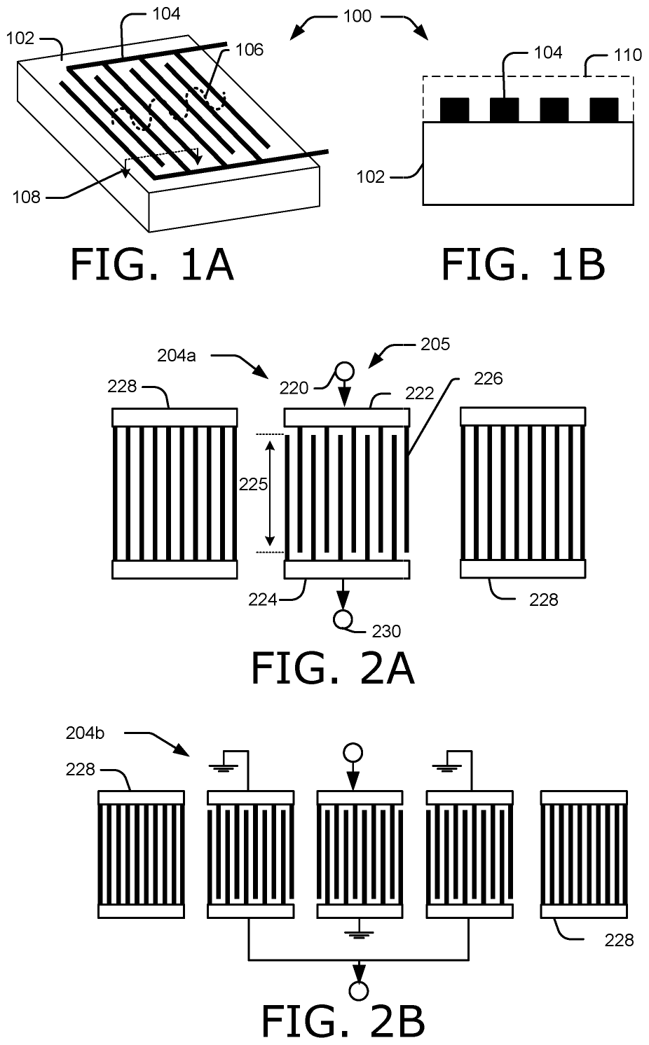

FIG. 1A is a perspective view of an example electroacoustic device 100. The electroacoustic device 100 may be configured as or be a portion of a SAW resonator. In certain descriptions herein, the electroacoustic device 100 may be referred to as a SAW resonator. However, there may be other electroacoustic device types that may be constructed based on the principles described herein.

The electroacoustic device 100 includes an electrode structure 104, that may be referred to as an interdigital transducer (IDT), on the surface of a piezoelectric material 102. The electrode structure 104 generally includes first and second comb-shaped electrode structures (conductive and generally metallic) with electrode fingers extending from two busbars towards each other arranged in an interlocking manner in between the two busbars (e.g., arranged in an interdigitated manner). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a cross-sectional view of the electroacoustic device 100 of FIG. 1A along a line segment 108 shown in FIG. 1A. The electroacoustic device 100 is illustrated by a simplified layer stack including the piezoelectric material 102 with the electrode structure 104 disposed on the piezoelectric material 102. The electrode structure 104 is electrically conductive and generally formed from metallic materials. The electrode structure 104 may alternatively be formed from materials that are electrically conductive, but non-metallic (e.g., graphene). The piezoelectric material 102 may be formed from a variety of materials such as quartz, lithium tantalate (LiTaO₃), lithium niobite (LiNbO₃), doped variants of these, other piezoelectric materials, or other crystals. The piezoelectric material 102 may be referred to as a “piezoelectric substrate,” but may also be referred to as a “piezoelectric layer,” such as in examples where there are additional layers below the piezoelectric material 102. It should be appreciated that more complicated layer stacks including layers of various materials may be possible within the stack. For example, optionally, a temperature compensation layer 110 denoted by the dashed lines may be disposed above the electrode structure 104. In another example, there could be layers (e.g., substrate or other layers) below the piezoelectric material 102. The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip-chip or other techniques) may also be included.

FIG. 2A is a top view of an example electrode structure 204a of an electroacoustic device. The electrode structure 204a has an IDT 205 that includes a first busbar 222 (e.g., first conductive segment or rail) electrically connected to a first terminal 220 and a second busbar 224 (e.g., second conductive segment or rail) spaced from the first busbar 222 and connected to a second terminal 230. A plurality of conductive fingers 226 are connected to either the first busbar 222 or the second busbar 224 in an interdigitated manner. Fingers 226 connected to the first busbar 222 extend towards the second busbar 224, but do not connect to the second busbar 224 so that there is a small gap between the ends of these fingers 226 and the second busbar 224. Likewise, fingers 226 connected to the second busbar 224 extend towards the first busbar 222, but do not connect to the first busbar 222 so that there is a small gap between the ends of these fingers 226 and the first busbar 222. Similarly, small gaps may also be formed between fingers 226 and any structure extending from the first busbar 222 or the second busbar 224 (e.g., stub fingers).

Between the busbars, there is an overlap region including a central region where a portion of one finger overlaps with a portion of an adjacent finger as illustrated by the central region 225. This central region 225 including the overlap may be referred to as the aperture, track, or active region where electric fields are produced between the fingers 226 to cause an acoustic wave to propagate in this region of the piezoelectric material 102. The periodicity of the fingers 226 is referred to as the pitch of the IDT. The pitch may be indicated in various ways. For example, in certain aspects, the pitch may correspond to a magnitude of a distance between fingers in the central region 225. This distance may be defined, for example, as the distance between center points of each of the fingers (and may be generally measured between a right (or left) edge of one finger and the right (or left) edge of an adjacent finger when the fingers have uniform width). In certain aspects, an average of distances between adjacent fingers may be used for the pitch. The frequency at which the piezoelectric material vibrates is a main resonance frequency of the electrode structure 204a. This frequency is determined at least in part by the pitch of the IDT 205 and other properties of the electroacoustic device 100.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the converted electrical signal may be provided as an output, such as to one of the first terminal 220 or the second terminal 230, while the other terminal may function as an input.

A variety of electrode structures are possible. FIG. 2A may generally illustrate a one-port configuration. Other configurations (e.g., two-port configurations) are also possible. For example, the electrode structure 204a may have an input IDT 205 where each terminal 220 and 230 functions as an input. In this event, an adjacent output IDT (not illustrated) that is positioned between the reflectors 228 and adjacent to the input IDT 205 may be provided to convert the acoustic wave propagating in the piezoelectric material 102 to an electrical signal to be provided at output terminals of the output IDT.

FIG. 2B is a top view of another example electrode structure 204b of an electroacoustic device. In this case, a dual-mode SAW (DMS) electrode structure 204b is illustrated, the DMS structure being a structure that may induce multiple resonances. The electrode structure 204b includes multiple IDTs arranged between reflectors 228 and connected as illustrated. The electrode structure 204b is provided to illustrate the variety of electrode structures that principles described herein may be applied to including the electrode structures 204a and 204b of FIGS. 2A and 2B.

It should be appreciated that while a certain number of fingers 226 are illustrated, the number of actual fingers and length(s) and width(s) of the fingers 226 and busbars may be different in an actual implementation. Such parameters depend on the particular application and desired filter characteristics. In addition, a SAW filter may include multiple interconnected electrode structures each including multiple IDTs to achieve a desired passband (e.g., multiple interconnected resonators or IDTs to form a desired filter transfer function).

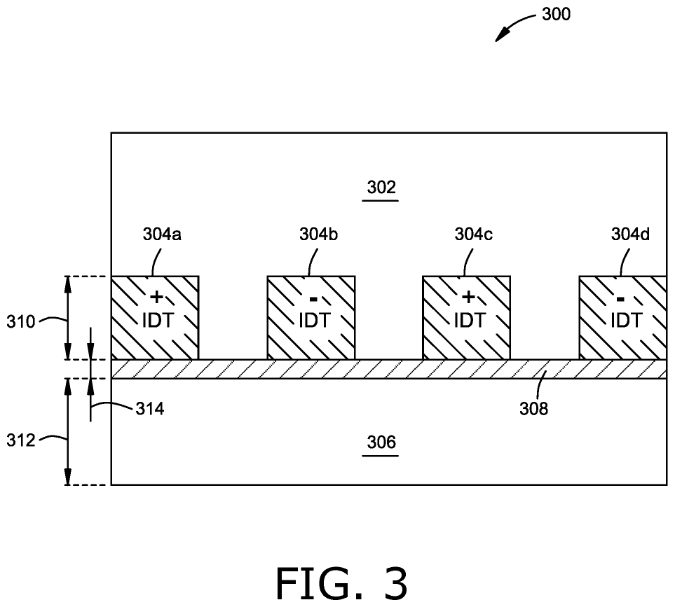

FIG. 3 is a cross-sectional view of an example electroacoustic device 300. The electroacoustic device 300 includes an IDT comprising a first electrode having a first plurality of fingers 304a and 304c, and a second electrode having a second plurality of fingers 304b and 304d that are interdigitated with the first plurality of fingers 304a and 304c of the first electrode. As shown, the plurality of fingers 304a and 304c of the first electrode have polarity opposite that of the plurality of fingers 304b and 304d of the second electrode. The plurality of fingers 304a-d of the IDT have a height 310, which may be between 80 nm to 500 nm, for example. Although only four fingers 304a-d are shown in FIG. 3 to illustrate the concept, it is to be understood that the IDT may include more or less than four fingers.

A material 302 may be disposed above and between the fingers 304a-d of the IDT. The material 302 may be air, for example, when the electroacoustic device 300 is a standard SAW device. Alternatively, the material 302 may be a dielectric material such as silicon dioxide (SiO₂) if the electroacoustic device 300 is a temperature-compensated surface acoustic wave (TCSAW) device. The material 302 may have a low relative permittivity (e.g., εᵣ=1 for air and εᵣ=3.9 for SiO₂).

The electroacoustic device 300 (e.g., that may be configured as or be a part of a SAW resonator) is similar to the electroacoustic device 100 of FIG. 1A, but has a different layer stack. In particular, the electroacoustic device 300 includes a continuous thin dielectric layer 308 that is provided on (or at least above) a piezoelectric layer 306 having a height 312. For other aspects, the dielectric layer 308 may be absent. The piezoelectric layer 306, for example, may comprise lithium tantalate (LiTaO₃), lithium niobite (LiNbO₃), some doped variant thereof, or any other suitable material. The piezoelectric layer 306 may also include other layers, such as a substrate material or other layers below the piezoelectric layer 306.

As shown in FIG. 3, the dielectric layer 308 has a height 314, which may also be referred to as a thickness. It may be desirable to deposit the dielectric layer 308 in a very thin layer to avoid loss of coupling between the piezoelectric layer 306 and the fingers 304a-d of the electrodes. For example, the height 314 of the continuous dielectric layer 308 may be 2.5 nm. In general, the piezoelectric layer 306 may be substantially thicker than the dielectric layer 308 (e.g., potentially on the order of 20,000 to 200,000 times thicker as one example, or more). Additionally, the IDT electrode fingers 304a-d may be substantially thicker than the dielectric layer 308 (e.g., potentially on the order of up to 250 times thicker as one example). Stated another way, height 310 and height 312 may be substantially greater than height 314, by at least an order of magnitude.

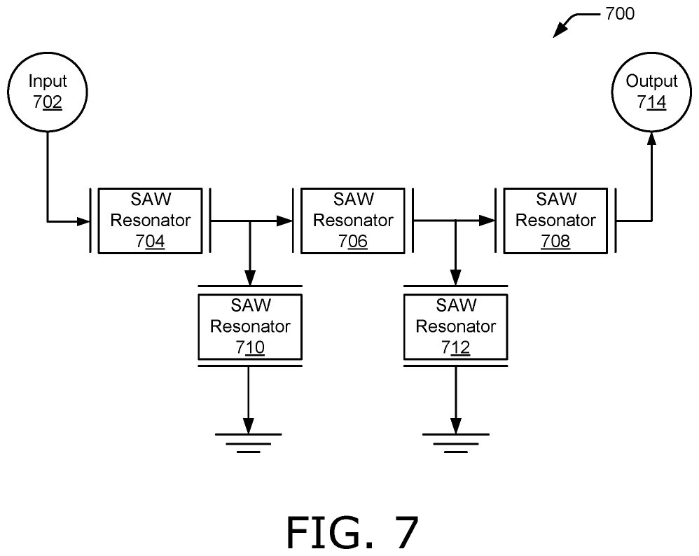

According to certain aspects of the present disclosure, the electroacoustic device 300 may be implemented in a filter or duplexer of a radio frequency (RF) circuit for use in a wireless communications device. Such a wireless communications device is described in further detail in the description of FIGS. 7-9.

Example SAW Device with High-κ Material Between Electrodes

Certain aspects of the present disclosure are directed toward passive, frequency-selective temperature compensated (TC) surface acoustic wave (SAW) devices for wireless communication applications. The radio frequency (RF) performance of a TCSAW filter may be strongly related to the static capacitance of the individual acoustic tracks. The capacitance of acoustic structures may be influenced by the number of interdigitated transducer (IDT) fingers and/or the track aperture. In some cases, there may be a minimum size specification for acoustic active parts (acoustic structures) of a TCSAW filter to fulfill the filter's RF specification. Therefore, further miniaturization of TCSAW devices is challenging due to this minimum size specification of the acoustic structures.

In some cases, the static capacitance of the IDT may be increased by introducing dielectric materials with high relative permittivity (high-dielectric-constant (high-κ) materials) in regions with high electric field strength (e.g., between the electrode fingers of the IDT). In an aspect, an example of a high-κ material that may be used includes a dielectric material that has a dielectric-constant that is greater than a dielectric-constant of silicon dioxide (SiO₂), whereas an example of a low-κ material that may be used includes a dielectric material that has a dielectric-constant that is equal to or less than a dielectric-constant of SiO₂. Further examples are described hereafter. Increased static capacitance of the acoustic structure may reduce the minimum size specification for acoustic active parts of the RF filter, allowing for a smaller chip size and reduced costs.

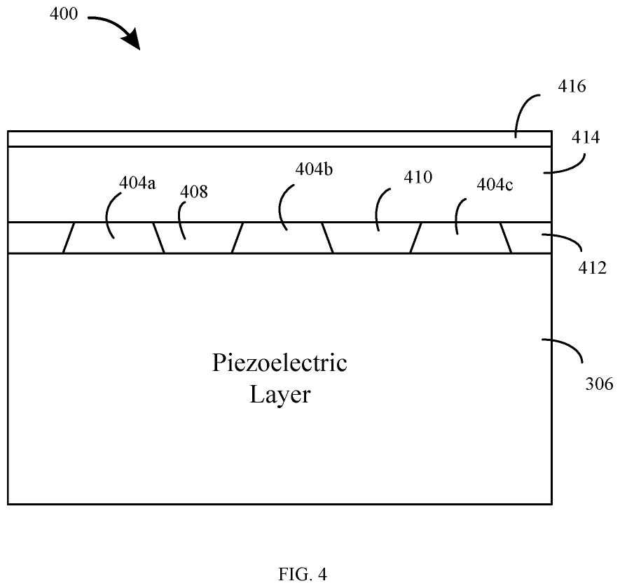

FIG. 4 illustrates a cross-section of a SAW device 400 with an IDT and with high-κ material disposed between electrode fingers of the IDT, in accordance with certain aspects of the present disclosure. As shown, the SAW device 400 includes a piezoelectric layer 306, above which are disposed electrode finger 404a, electrode finger 404b, and electrode finger 404c (e.g., corresponding to fingers 304a, 304b, 304c of FIG. 3). High-K material 408, 410, 412 may be disposed between electrode fingers of the IDT. For example, high-κ material 410 may be disposed between electrode finger 404b and electrode finger 404c, as shown.

Any suitable high-κ material may be used. For example, the high-κ material may be aluminum nitride (AlN), hafnium dioxide (HfO₂), titanium dioxide (TiO₂), zirconium dioxide (ZrO₂), aluminum oxide (Al₂O₃), hafnium silicon oxide (HfSiO₂), tantalum pentoxide (Ta₂O₅), niobium oxide (Nb₂O₅), scandium oxide (Sc₂O₃), or strontium titanate (SrTiO₃).

In some aspects, the height of the high-κ material (e.g., high-κ material 410) from the piezoelectric layer may be 60% or more of the height of the electrode finger (e.g., electrode finger 404b or electrode finger 404c). In some aspects, the height of the high-κ material (e.g., high-κ material 410) from the piezoelectric layer may be 50% or more of the height of the electrode finger (e.g., electrode finger 404b or electrode finger 404c). In some aspects, the height of the high-κ material may be the same as the height of the electrode finger. The height of the high-κ material may be considered to be the same as the height of the electrode finger if the heights of the high-κ material and the electrode are within 30 nm (e.g., the height of the high-κ material is 30 nm more than the height of the electrode).

In some aspects, above the electrodes and high-κ material is a low-material, such as a temperature compensation layer 414 (e.g., silicon dioxide (SiO₂), which may be doped with fluorine) and a passivation layer 416 (e.g., silicon nitride (Si₃N₄)). In SAW devices, some materials become softer (less stiff) with increasing temperature. With reduced stiffness at higher temperatures, the frequency response of the SAW device changes. The temperature compensation layer is used to stabilize the frequency response of the SAW device across different temperatures. The temperature compensation layer becomes stiffer with increased temperature and compensates for the impact of other materials of the SAW device becoming softer with increased temperature, providing a more stabilized frequency response with respect to changes in temperature.

By including the high-κ material between the IDT electrodes, the IDT's size may be reduced by reducing the number of fingers of the IDT. In some cases, the aperture (e.g., central region 225 shown in FIG. 2A representing the electrode overlap of the IDT) may also be reduced.

In some cases, a metal chemical mechanical planarization (CMP) process may be used. For example, the facility may deposit and structure the high-κ material first. The facility may then deposit the metal for the electrodes and remove a portion of the metal via CMP. Depending on the interaction of the high-κ material with the CMP process, the high-κ material height may be 100% of the electrode height.

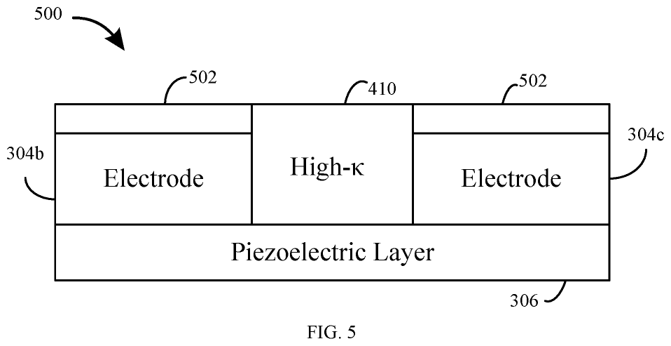

In some cases, the SAW device may be manufactured using an oxide CMP process. In this case, a manufacturing facility may first deposit metal and structure the electrodes of the IDT. After, the facility may deposit the high-κ material. The facility may then remove a portion of the high-κ material with CMP, which may result in around a 20-30 nm high-κ material film on top of the electrodes. Thus, the high-κ material height between the electrodes may (e.g., depending on the deposition method) reach 100% (or more) of the electrode height. In some cases, an oxide CMP process with a SiO₂ sacrificial layer may be used as described in more detail with respect to FIG. 5.

FIG. 5 illustrates a SAW device 500 with high-κ material manufactured using an oxide CMP process with a sacrificial layer, in accordance with certain aspects of the present disclosure. In this case, a sacrificial layer 502 (e.g., of SiO₂) may be formed on top of the structured electrodes, as shown. Removing the high-κ material with CMP may result in a 20-30 nm thick SiO₂ on top of the electrodes, as shown. In this case, the high-K material height may be 20-30 nm over the electrode finger height, as shown.

### Example Operations for Fabricating a SAW Device

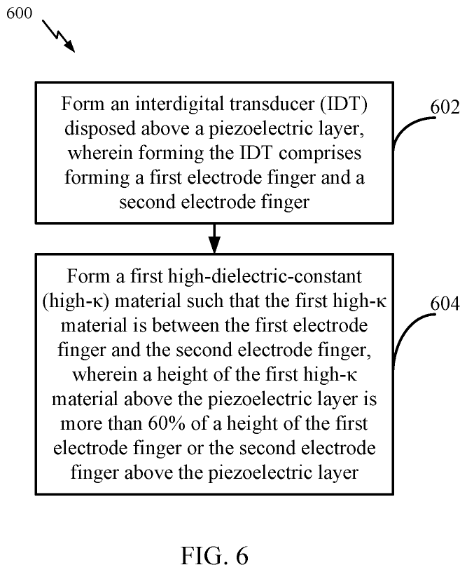

FIG. 6 is a block diagram of example operations 600 for fabricating a surface acoustic wave (SAW) device (e.g., a TCSAW device), such as the SAW device 400 or 500. The operations 600 may be performed by a manufacturing facility.

At block 602, the facility may form an interdigital transducer (IDT) (e.g., IDT 205) disposed above a piezoelectric layer (e.g., piezoelectric layer 306). Forming the IDT may include forming a first electrode finger (e.g., electrode finger 404a) and a second electrode finger (e.g., electrode finger 404b).

At block 604, the facility may form first high-dielectric-constant (high-κ) material (e.g., high-κ material 408) such that the first high-κ material is between the first electrode finger and the second electrode finger. A height of the first high-κ material above the piezoelectric layer is more than 60% of a height of the first electrode or the second electrode above the piezoelectric layer. In some aspects, the height of the first high-κ material may be the same as the height of the first electrode finger or the second electrode finger. The first high-material may include aluminum nitride (AlN), hafnium dioxide (HfO₂), titanium dioxide (TiO₂), zirconium dioxide (ZrO₂), aluminum oxide (Al₂O₃), hafnium silicon oxide (HfSiO₂), tantalum pentoxide (Ta₂O₅), niobium oxide (Nb₂O₅), scandium oxide (Sc₂O₃), or strontium titanate (SrTiO₃).

The first electrode finger and the second electrode finger may be formed before the first high-κ material in some cases. In other cases, the first electrode finger and the second electrode finger are formed after the first high-κ material.

In some aspects, the IDT also includes a third electrode finger (e.g., electrode finger 404c). The SAW device may also include second high-κ material (e.g., high-κ material 410) disposed between the second electrode finger and the third electrode finger. A height of the second high-κ material above the piezoelectric layer may be more than 60% of a height of the second electrode finger or the third electrode finger above the piezoelectric layer.

In some aspects, the facility forms low-κ material above the first electrode finger, the second electrode finger, and the first high-κ material. For example, the facility may form a temperature compensation layer (e.g., temperature compensation layer 414) above the IDT. The facility may form a passivation layer (e.g., passivation layer 416) above the temperature compensation layer.

Example Integration into a Filter and Wireless Communications Device

FIG. 7 is a schematic diagram of an electroacoustic filter circuit 700 that may include one or more of the electroacoustic devices 300, 400, and 500 of FIGS. 3-5. The filter circuit 700 provides one example of where the disclosed SAW devices may be used. The filter circuit 700 includes an input terminal 702 and an output terminal 714. Between the input terminal 702 and the output terminal 714, a ladder-type network of SAW resonators is provided. The filter circuit 700 includes a first SAW resonator 704, a second SAW resonator 706, and a third SAW resonator 708 all electrically connected in series between the input terminal 702 and the output terminal 714. A fourth SAW resonator 710 (e.g., a shunt resonator) has a first terminal connected to a node between the first SAW resonator 704 and the second SAW resonator 706 and has a second terminal connected to a reference potential node (e.g., electric ground) for the filter circuit 700. A fifth SAW resonator 712 (e.g., a shunt resonator) has a first terminal connected to a node between the second SAW resonator 706 and the third SAW resonator 708 and has a second terminal connected to the reference potential node. The electroacoustic filter circuit 700 may, for example, be a bandpass filter circuit having a passband with a selected frequency range (e.g., in a range between 500 MHz and 6 GHZ).

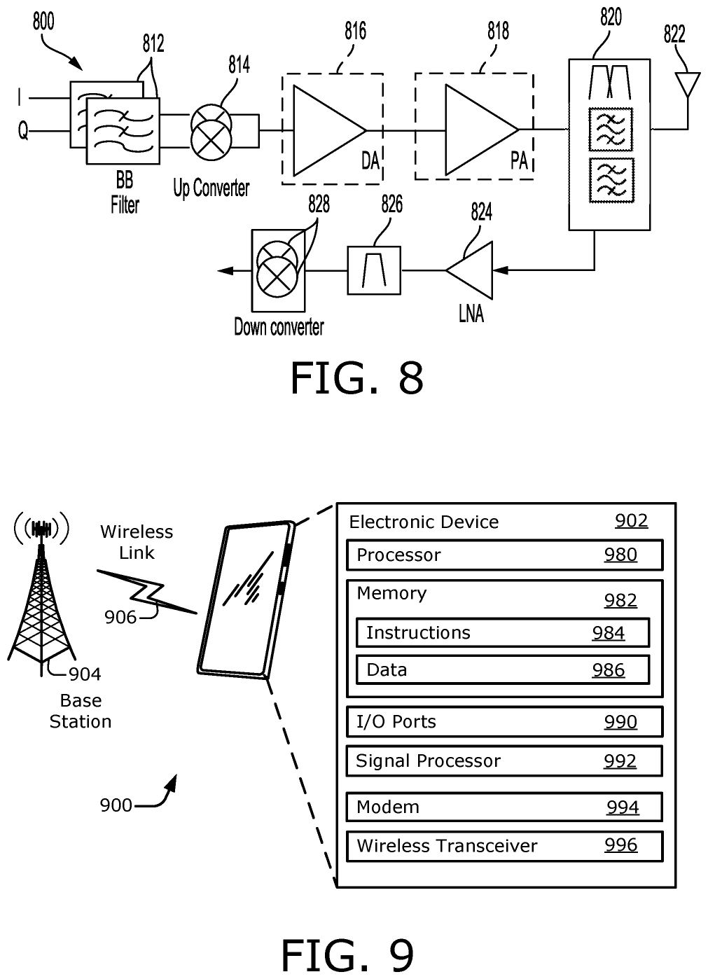

FIG. 8 is a functional block diagram of at least a portion of an example simplified wireless transceiver circuit 800 in which the filter circuit 700 of FIG. 7 may be employed. The transceiver circuit 800 is configured to receive signals/information for transmission (shown as in-phase (I) and quadrature (Q) values) which is provided to one or more baseband (BB) filters 812. The filtered output is provided to one or more mixers 814 for upconversion to radio frequency (RF) signals. The output from the one or more mixers 814 may be provided to a driver amplifier (DA) 816 whose output may be provided to a power amplifier (PA) 818 to produce an amplified signal for transmission. The amplified signal is output to the antenna 822 through one or more filters 820 (e.g., duplexers if used as a frequency division duplex transceiver or other filters). The one or more filters 820 may include the filter circuit 700 of FIG. 7.

The antenna 822 may be used for both wirelessly transmitting and receiving data. The transceiver circuit 800 includes a receive path through the one or more filters 820 to be provided to a low noise amplifier (LNA) 824 and a further filter 826 and then downconverted from the receive frequency to a baseband frequency through one or more mixer circuits 828 before the signal is further processed (e.g., provided to an analog-to-digital converter (ADC) and then demodulated or otherwise processed in the digital domain). There may be separate filters for the receive circuit (e.g., may have a separate antenna or have separate receive filters) that may be implemented using the filter circuit 700 of FIG. 7.

FIG. 9 is a diagram of an environment 900 that includes an electronic device 902, in which aspects of the present disclosure may be practiced. In the environment 900, the electronic device 902 communicates with a base station 904 (e.g., a gNB) through a wireless link 906. As shown, the electronic device 902 is depicted as a smartphone. However, the electronic device 902 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, wearable device, sensor or security device, asset tracker, and so forth.

The base station 904 communicates with the electronic device 902 via the wireless link 906, which may be implemented as any suitable type of wireless link. Although depicted as a base station tower of a cellular radio network, the base station 904 may represent or be implemented as another device, such as a satellite, terrestrial broadcast tower, access point, peer-to-peer device, mesh network node, fiber optic line, another electronic device generally as described above, and so forth. Hence, the electronic device 902 may communicate with the base station 904 or another device via a wired connection, a wireless connection, or a combination thereof. The wireless link 906 can include a downlink of data or control information communicated from the base station 904 to the electronic device 902 and an uplink of other data or control information communicated from the electronic device 902 to the base station 904. The wireless link 906 may be implemented using any suitable communication protocol or standard, such as 3rd Generation Partnership Project Long-Term Evolution (3GPP LTE), 3GPP NR 5G, IEEE 802.11, IEEE 802.16, Bluetooth™, and so forth.

The electronic device 902 includes a processor 980 and a memory 982. The memory 982 may be or form a portion of a computer-readable storage medium. The processor 980 may include any type of processor, such as an application processor or a multi-core processor, that is configured to execute processor-executable instructions (e.g., code) stored by the memory 982. The memory 982 may include any suitable type of data storage media, such as volatile memory (e.g., random access memory (RAM)), non-volatile memory (e.g., flash memory), optical media, magnetic media (e.g., disk or tape), and so forth. In the context of this disclosure, the memory 982 is implemented to store instructions 984, data 986, and other information of the electronic device 902, and thus when configured as or part of a computer-readable storage medium, the memory 982 does not include transitory propagating signals or carrier waves.

The electronic device 902 may also include input/output ports 990. The I/O ports 990 enable data exchanges or interaction with other devices, networks, or users or between components of the device.

The electronic device 902 may further include a signal processor (SP) 992 (e.g., such as a digital signal processor (DSP)). The signal processor 992 may function similar to the processor and may be capable of executing instructions and/or processing information in conjunction with the memory 982.

For communication purposes, the electronic device 902 also includes a modem 994, a wireless transceiver 996, and an antenna (not shown). The wireless transceiver 996 provides connectivity to respective networks and other electronic devices connected therewith using radio frequency (RF) wireless signals and may include the transceiver circuit 800 of FIG. 8. The wireless transceiver 996 may facilitate communication over any suitable type of wireless network, such as a wireless local area network (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

### Example Aspects

In addition to the various aspects described above, specific combinations of aspects are within the scope of the disclosure, some of which are detailed in the clauses below:
Aspect 1: A surface acoustic wave (SAW) device comprising: a piezoelectric layer; an interdigital transducer (IDT) disposed above the piezoelectric layer and comprising a first electrode finger and a second electrode finger; and a first high-dielectric-constant (high-κ) material disposed between the first electrode finger and the second electrode finger, wherein a height of the first high-κ material above the piezoelectric layer is more than 60% of a height of the first electrode finger or the second electrode finger above the piezoelectric layer.
Aspect 2: The SAW device of Aspect 1, wherein the first high-κ material has a dielectric-constant that is greater than a dielectric-constant of silicon dioxide.
Aspect 3: The SAW device of Aspect 1 or 2, wherein the height of the first high-κ material is at least as high as the height of the first electrode finger or the second electrode finger.
Aspect 4: The SAW device according to any of Aspects 1-3, wherein: the IDT further comprises a third electrode finger; the SAW device further comprises a second high-κ material disposed between the second electrode finger and the third electrode finger; and a height of the second high-κ material above the piezoelectric layer is more than 60% of a height of the second electrode finger or the third electrode finger above the piezoelectric layer.
Aspect 5: The SAW device according to any of Aspects 1-4, further comprising a temperature compensation layer disposed above the IDT.
Aspect 6: The SAW device of Aspect 5, further comprising a passivation layer disposed above the temperature compensation layer.
Aspect 7: The SAW device according to any of Aspects 1-6, wherein the SAW device comprises a temperature compensation (TC) SAW device.
Aspect 8: The SAW device according to any of Aspects 1-7, further comprising low-κ material disposed above the first electrode finger, the second electrode finger, and the first high-material.
Aspect 9: The SAW device of Aspect 8, wherein the low-κ material comprises silicon dioxide.
Aspect 10: The SAW device according to any of Aspects 1-9, wherein the first high-κ material comprises aluminum nitride (AlN), hafnium dioxide (HfO₂), titanium dioxide (TiO₂), zirconium dioxide (ZrO₂), aluminum oxide (Al₂O₃), hafnium silicon oxide (HfSiO₂), tantalum pentoxide (Ta₂O₅), niobium oxide (Nb₂O₅), scandium oxide (Sc₂O₃), or strontium titanate (SrTiO₃).
Aspect 11: A method of fabricating a surface acoustic wave (SAW) device comprising: forming an interdigital transducer (IDT) disposed above a piezoelectric layer, wherein forming the IDT comprises forming a first electrode finger and a second electrode finger; and forming a first high-dielectric-constant (high-κ) material such that the first high-material is between the first electrode finger and the second electrode finger, wherein a height of the first high-κ material above the piezoelectric layer is more than 60% of a height of the first electrode finger or the second electrode finger above the piezoelectric layer.
Aspect 12: The method of Aspect 11, wherein the first electrode finger and the second electrode finger are formed before the first high-κ material.
Aspect 13: The method of Aspect 11 or 12, wherein the first electrode finger and the second electrode finger are formed after the first high-κ material.
Aspect 14: The method according to any of Aspects 11-13, wherein the height of the first high-κ material is the same as the height of the first electrode finger or the second electrode finger.
Aspect 15: The method according to any of Aspects 11-14, wherein: the IDT further comprises a third electrode finger; the SAW device further comprises a second high-κ material disposed between the second electrode finger and the third electrode finger; and a height of the second high-κ material above the piezoelectric layer is more than 60% of a height of the second electrode finger or the third electrode finger above the piezoelectric layer.
Aspect 16: The method according to any of Aspects 11-15, further comprising forming a temperature compensation layer above the IDT.
Aspect 17: The method of Aspect 16, further comprising forming a passivation layer above the temperature compensation layer.
Aspect 18: The method according to any of Aspects 9-17, further comprising forming low-κ material above the first electrode finger, the second electrode finger, and the first high-κ material.
Aspect 19: A wireless device comprising: a radio frequency (RF) circuit; and a surface acoustic wave (SAW) filter coupled to the RF circuit, the SAW filter comprising: a piezoelectric layer; an interdigital transducer (IDT) disposed above the piezoelectric layer and comprising a first electrode finger and a second electrode finger; and a high-dielectric-constant (high-κ) material disposed between the first electrode finger and the second electrode finger, wherein a height of the high-κ material above the piezoelectric layer is more than 60% of a height of the first electrode finger or the second electrode finger above the piezoelectric layer.
Aspect 20: The wireless device of Aspect 19, wherein the height of the high-K material is the same as the height of the first electrode finger or the second electrode finger.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor.

By way of example, an element, or any portion of an element, or any combination of elements described herein may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoCs), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuit.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. A surface acoustic wave (SAW) device comprising:
a piezoelectric layer;
an interdigital transducer (IDT) disposed above the piezoelectric layer and comprising a first electrode finger and a second electrode finger; and
a first high-dielectric-constant (high-κ) material disposed between the first electrode finger and the second electrode finger, wherein a height of the first high-κ material above the piezoelectric layer is more than 60% of a height of the first electrode finger or the second electrode finger above the piezoelectric layer.

2. The SAW device of claim 1, wherein the first high-κ material has a dielectric-constant that is greater than a dielectric-constant of silicon dioxide.

3. The SAW device of claim 1, wherein the height of the first high-κ material is at least as high as the height of the first electrode finger or the second electrode finger.

4. The SAW device of claim 1, wherein:
the IDT further comprises a third electrode finger;
the SAW device further comprises a second high-κ material disposed between the second electrode finger and the third electrode finger; and
a height of the second high-κ material above the piezoelectric layer is more than 60% of a height of the second electrode finger or the third electrode finger above the piezoelectric layer.

5. The SAW device of claim 1, further comprising a temperature compensation layer disposed above the IDT.

6. The SAW device of claim 5, further comprising a passivation layer disposed above the temperature compensation layer.

7. The SAW device of claim 1, wherein the SAW device comprises a temperature compensation (TC) SAW device.

8. The SAW device of claim 1, further comprising low-κ material disposed above the first electrode finger, the second electrode finger, and the first high-κ material.

9. The SAW device of claim 8, wherein the low-κ material comprises silicon dioxide.

10. The SAW device of claim 1, wherein the first high-κ material comprises aluminum nitride (AlN), hafnium dioxide (HfO₂), titanium dioxide (TiO₂), zirconium dioxide (ZrO₂), aluminum oxide (Al₂O₃), hafnium silicon oxide (HfSiO₂), tantalum pentoxide (Ta₂O₅), niobium oxide (Nb₂O₅), scandium oxide (Sc₂O₃), or strontium titanate (SrTiO₃).

11. A method of fabricating a surface acoustic wave (SAW) device comprising:
forming an interdigital transducer (IDT) disposed above a piezoelectric layer, wherein forming the IDT comprises forming a first electrode finger and a second electrode finger; and
forming a first high-dielectric-constant (high-κ) material such that the first high-κ material is between the first electrode finger and the second electrode finger, wherein a height of the first high-κ material above the piezoelectric layer is more than 60% of a height of the first electrode finger or the second electrode finger above the piezoelectric layer.

12. The method of claim 11, wherein the first electrode finger and the second electrode finger are formed before the first high-κ material.

13. The method of claim 11, wherein the first electrode finger and the second electrode finger are formed after the first high-κ material.

14. The method of claim 11, wherein the height of the first high-material is the same as the height of the first electrode finger or the second electrode finger.

15. The method of claim 11, wherein:
the IDT further comprises a third electrode finger;
the SAW device further comprises a second high-κ material disposed between the second electrode finger and the third electrode finger; and
a height of the second high-κ material above the piezoelectric layer is more than 60% of a height of the second electrode finger or the third electrode finger above the piezoelectric layer.

16. The method of claim 11, further comprising forming a temperature compensation layer above the IDT.

17. The method of claim 16, further comprising forming a passivation layer above the temperature compensation layer.

18. The method of claim 11, further comprising forming low-κ material above the first electrode finger, the second electrode finger, and the first high-κ material.

19. A wireless device comprising:
a radio frequency (RF) circuit; and
a surface acoustic wave (SAW) filter coupled to the RF circuit, the SAW filter comprising:
a piezoelectric layer;
an interdigital transducer (IDT) disposed above the piezoelectric layer and comprising a first electrode finger and a second electrode finger; and
a high-dielectric-constant (high-κ) material disposed between the first electrode finger and the second electrode finger, wherein a height of the high-κ material above the piezoelectric layer is more than 60% of a height of the first electrode finger or the second electrode finger above the piezoelectric layer.

20. The wireless device of claim 19, wherein the height of the high-material is the same as the height of the first electrode finger or the second electrode finger.
